(19) United States
(12) Patent Application Publication
(10) Pub. No.: US 2017/0241014 A1
(43) Pub. Date: Aug. 24, 2017

(54) RUTHENIUM METAL DEPOSITION METHOD FOR ELECTRICAL CONNECTIONS

(71) Applicant: Tokyo Electron Limited, Tokyo (JP)

(72) Inventors: Kai-Hung Yu, Watervliet, NY (US); Gerrit J. Leusink, Rexford, NY (US); Cory Wajda, Sand Lake, NY (US); Tadahiro Ishizaka, Hokuto City (JP); Takahiro Hakamata, Albany, NY (US)

(21) Appl. No.: 15/435,970

(22) Filed: Feb. 17, 2017

Related U.S. Application Data
(60) Provisional application No. 62/297,623, filed on Feb. 19, 2016.

(51) Int. Cl. C23C 16/16; C23C 16/44; C23C 16/455

(52) U.S. Cl. CPC C23C 16/16; C23C 16/45523; C23C 16/45557; C23C 16/4408

(57) ABSTRACT

A method for material deposition is described in several embodiments. According to one embodiment, the method includes providing a substrate defining features to receive a deposition of material, initiating a flow of a Ru carbonyl precursor to the substrate, the Ru carbonyl precursor decomposing within the defined features such that a Ru metal film is deposited on surfaces of the defined features and CO gas is released, and stopping the flow of the Ru carbonyl precursor to the substrate. The method further includes flowing additional CO gas to the substrate after stopping the flow of the Ru carbonyl precursor to the substrate, and repeatedly cycling between process steps of flowing the Ru carbonyl precursor to the substrate and flowing the additional CO gas to the substrate. In one embodiment, the Ru carbonyl precursor contains Ru₃(CO)₁₂.

### CROSS-REFERENCE TO RELATED APPLICATIONS

This application is related to and claims priority to U.S. provisional application Ser. No. 62/297,623 filed on Feb. 19, 2016, the entire contents of which are herein incorporated by reference.

### FIELD OF THE INVENTION

This disclosure relates to material deposition techniques including techniques for creating electrical connections for microelectronic devices.

### BACKGROUND OF THE INVENTION

An integrated circuit contains various semiconductor devices and a plurality of conducting metal paths that provide electrical power to the semiconductor devices and allow these semiconductor devices to share and exchange information. Within the integrated circuit, metal layers are stacked on top of one another using inter-metal or interlayer dielectric layers that insulate the metal layers from each other.

Normally, each metal layer must form an electrical contact to at least one additional metal layer. Such electrical contact is achieved by etching a feature (i.e., a via) in the interlayer dielectric that separates the metal layers, and filling the resulting via with a metal to create an interconnect. Metal layers typically occupy etched pathways in the interlayer dielectric. A “via” normally refers to any feature such as a hole, line or other similar feature formed within a dielectric layer that provides an electrical connection through the dielectric layer to a conductive layer underlying the dielectric layer. Similarly, metal layers connecting two or more vias are normally referred to as trenches.

The use of copper (Cu) metal in multilayer metallization schemes for manufacturing integrated circuits creates problems due to high mobility of Cu atoms in dielectrics, such as SiO₂, and Cu atoms may create electrical defects in silicon (Si). Thus, Cu metal layers, Cu filled trenches, and Cu filled vias are normally encapsulated with a barrier material to prevent Cu atoms from diffusing into the dielectrics and Si. Barrier layers are normally deposited on trench and via sidewalls and bottoms prior to Cu seed deposition, and may include materials that are preferably non-reactive and immiscible in Cu, provide good adhesion to the dielectrics and can offer low electrical resistivity.

An increase in device performance is normally accompanied by a decrease in device area or an increase in device density. An increase in device density requires a decrease in via dimensions used to form interconnects, including a larger aspect ratio (i.e., depth to width ratio). As via dimensions decrease, and aspect ratios increase, it becomes increasingly more challenging to form diffusion barrier layers with adequate thickness on the sidewalls of the vias, while also providing enough volume for the metal layer in the via. In addition, as via and trench dimensions decrease and the thicknesses of the layers in the vias and trenches decrease, the material properties of the layers and the layer interfaces become increasingly more important. In particular, the processes forming those layers need to be carefully integrated into a manufacturable process sequence where good control is maintained for all the steps of the process sequence.

### SUMMARY OF THE INVENTION

A method for material deposition is described in several embodiments. According to one embodiment, the method includes providing a substrate defining features to receive a deposition of material, initiating a flow of a ruthenium (Ru) carbonyl precursor to the substrate, the Ru carbonyl precursor decomposing within the defined features such that a Ru metal film is deposited on surfaces of the defined features and CO gas is released, and stopping the flow of the Ru carbonyl precursor to the substrate. The method further includes flowing additional CO gas to the substrate after stopping the flow of the Ru carbonyl precursor to the substrate, and repeatedly cycling between process steps of flowing the Ru carbonyl precursor to the substrate and flowing the additional CO gas to the substrate. In one example, the Ru carbonyl precursor contains Ru3(CO)12. In one embodiment, a sufficient volume of the additional CO gas is flowed to the substrate to increase the density of Ru metal nuclei on the substrate as compared to the density of the Ru metal nuclei on the substrate without presence of the additional CO gas.

According to another embodiment of the invention, the method includes providing a substrate defining features to receive a deposition of material, initiating a flow of a Ru carbonyl precursor to the substrate, the Ru carbonyl precursor decomposing within the defined features such that a Ru metal film is deposited on surfaces of the defined features and carbon monoxide (CO) gas is released, and stopping the flow of the Ru carbonyl precursor to the substrate. The method further includes initiating a flow of additional CO gas to the substrate after stopping flow of the Ru carbonyl precursor to the substrate, and stopping the flow of the additional CO gas to the substrate, and repeatedly cycling between process steps of flowing the Ru carbonyl precursor to the substrate and flowing the additional CO gas to the substrate. In one example, the Ru carbonyl precursor contains Ru₃(CO)₁₂.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 depicts a schematic view of a deposition system according to an embodiment of the invention;

FIG. 2 schematically shows gas flows during cyclical Ru metal deposition according to an embodiment of the invention;

FIG. 3 shows measured haze of Ru metal films as a function of Ru metal thickness and deposition method according to an embodiment of the invention;

FIGS. 4A and 4B show cross-sectional transmission electron microscope (TEM) images of 1 nm thick Ru metal films according to an embodiment of the invention;

FIGS. 5A-5C schematically show through cross-sectional views Ru metal deposition without the use of additional CO gas; and

FIGS. 6A-6C schematically show through cross-sectional views Ru metal deposition by cyclical deposition using additional CO gas.

### DETAILED DESCRIPTION OF SEVERAL EMBODIMENTS

Methods for depositing smooth and continuous Ru metal films for microelectronic devices are described in several embodiments.

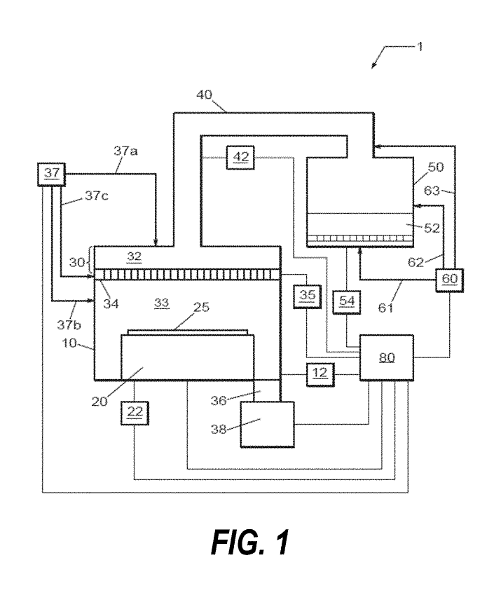

FIG. 1 illustrates a deposition system 1 for depositing a Ru metal film on a substrate from a Ru carbonyl precursor according to an embodiment of the invention. The following sections describe the use of Ru₃(CO)₁₂, however other ruthenium carbonyl precursors may be used without departing from the scope of the invention. The deposition system 1 includes a process chamber 10 having a substrate holder 20 configured to support a substrate 25 upon which the Ru metal film is formed. The process chamber 10 is coupled to a metal precursor vaporization system 50 via a vapor precursor delivery system 40.

The process chamber 10 is further coupled to a vacuum pumping system 38 through a duct 36, wherein the vacuum pumping system 38 is configured to evacuate the process chamber 10, vapor precursor delivery system 40, and metal precursor vaporization system 50 to a pressure suitable for forming the Ru metal film on the substrate 25, and suitable for vaporization of the Ru carbonyl precursor 52 in the metal precursor vaporization system 50.

The metal precursor vaporization system 50 is configured to store a Ru carbonyl precursor 52, to heat the Ru carbonyl precursor 52 to a temperature sufficient for vaporizing the Ru carbonyl precursor 52, and to introduce Ru carbonyl precursor vapor to the vapor precursor delivery system 40. Ru₃(CO)₁₂ is a solid under the selected heating conditions in the metal precursor vaporization system 50, however, those skilled in the art will appreciate that other ruthenium carbonyl precursors that are liquids under the selected heating conditions can be used without departing from the scope of the invention. Although not shown, the vapor precursor delivery system 40 can include one or more control valves, one or more filters, and a mass flow controller.

In order to achieve the desired temperature for subliming the solid Ru carbonyl precursor 52, the metal precursor vaporization system 50 is coupled to a vaporization temperature control system 54 configured to control the vaporization temperature. For instance, the temperature of the Ru carbonyl precursor 52 may be elevated to between approximately 70° C. to approximately 100° C., or higher, in order to sublime the Ru₃(CO)₁₂. In one example, temperature of the Ru carbonyl precursor 52 may be elevated to between approximately 78° C. to approximately 82° C. in order to sublime the Ru₃(CO)₁₂. As the Ru carbonyl precursor 52 is heated to cause sublimation, a CO gas carrier gas can be passed over or through the Ru carbonyl precursor 52, or any combination thereof. The CO carrier gas contains CO and optionally an inert carrier gas, such as N₂, or a noble gas (i.e., He, Ne, Ar, Kr, or Xe), or a combination thereof.

For example, a gas supply system 60 is coupled to the metal precursor vaporization system 50, and it is configured to, for instance, supply CO gas, an inert gas, or a mixture thereof, beneath the Ru carbonyl precursor 52 via feed line 61, or over the Ru carbonyl precursor 52 via feed line 62. In addition, or in the alternative, the gas supply system 60 is coupled to the vapor precursor delivery system 40 downstream from the metal precursor vaporization system 50 to supply the gas to the vapor of the Ru carbonyl precursor 52 via feed line 63 as or after it enters the vapor precursor delivery system 40. Although not shown, the gas supply system 60 can comprise a CO gas source, an inert gas source, one or more control valves, one or more filters, and a mass flow controller. For instance, the flow rate of the CO carrier gas can be between about 0.1 standard cubic centimeters per minute (sccm) and about 1000 sccm. Alternately, the flow rate of the CO carrier gas can be between about 10 sccm and about 500 sccm. Still alternately, the flow rate of the CO carrier gas can be between about 50 sccm and about 300 sccm. According to embodiments of the invention, the flow rate of the CO gas can range from approximately 0.1 sccm to approximately 1000 sccm. Alternately, the flow rate of the CO gas can be between about 1 sccm and about 500 sccm.

Downstream from the metal precursor vaporization system 50, the process gas containing the Ru carbonyl precursor vapor and the CO carrier gas flows through the vapor precursor delivery system 40 until it enters the process chamber 10 via a vapor distribution system 30 coupled thereto. The vapor precursor delivery system 40 can be coupled to a vapor line temperature control system 42 in order to control the vapor line temperature and prevent decomposition of the Ru carbonyl precursor vapor as well as condensation of the Ru carbonyl precursor vapor. Although not shown, the vapor precursor delivery system 40 can include one or more control valves, one or more filters, and a mass flow controller.

The vapor distribution system 30, which forms part of and is coupled to the process chamber 10, comprises a vapor distribution plenum 32 within which the vapor disperses prior to passing through a vapor distribution plate 34 and entering a processing zone 33 above substrate 25. In addition, the vapor distribution plate 34 can be coupled to a distribution plate temperature control system 35 configured to control the temperature of the vapor distribution plate 34.

Once the process gas containing the Ru carbonyl precursor vapor enters the processing zone 33 of process chamber 10, the Ru carbonyl precursor vapor thermally decomposes upon adsorption at the substrate surface due to the elevated temperature of the substrate 25, and a Ru metal layer is formed on the substrate 25. The substrate holder 20 is configured to elevate the temperature of the substrate 25 by virtue of the substrate holder 20 being coupled to a substrate temperature control system 22. For example, the substrate temperature control system 22 can be configured to elevate the temperature of the substrate 25 up to approximately 500° C. In one example, the temperature of the substrate 25 can be maintained between about 150° C. and about 250° C. during Ru metal deposition. In another example, the temperature of the substrate 25 can be maintained between about 190° C. and about 200° C. during Ru metal deposition. Additionally, the process chamber 10 can be coupled to a chamber temperature control system 12 configured to control the temperature of the chamber walls.

The CO gas in the CO carrier gas is used to reduce premature decomposition of the Ru carbonyl precursor vapor prior to entering the process chamber 10, including in the metal precursor vaporization system 50, the vapor precursor delivery system 40, and the vapor distribution system 30. The addition of the CO gas to the Ru carbonyl precursor vapor allows for increasing the vaporization temperature from approximately 40° C. to approximately 100° C., or higher. The elevated temperature increases the vapor pressure of the ruthenium carbonyl precursor, resulting in increased delivery of the Ru carbonyl precursor to the process chamber 10 and, hence, increased deposition rate of the Ru metal on the substrate 25.

The deposition system 1 contains an additional gas source 37 coupled to the process chamber 10. The additional gas source 37 is configured to add an additional gas to the process gas containing the metal-carbonyl precursor vapor and the CO gas. According to an embodiment of the invention, the additional gas can contain an inert gas (e.g., N₂, a noble gas (i.e., He, Ne, Ar, Kr, or Xe), or a combination thereof), a CO gas, or a combination thereof. The additional gas source 37 can be coupled to the vapor distribution system 30 via feed line 37a and configured to add the additional gas to the process gas in the vapor distribution plenum 32 before the process gas passes through the vapor distribution plate 34 into the processing zone 33. Alternately, the additional gas source 37 can be coupled to the process chamber 10 via feed line 37b and configured to add the additional gas to the process gas in the processing zone 33 above the substrate 25 in the process chamber 10 after the process gas passes through the vapor distribution plate 34. Still alternately, the additional gas source 37 can be coupled to the vapor distribution system 30 via feed line 37c and configured to add the additional gas to the process gas in the vapor distribution plate 34.

As will be appreciated by those skilled in the art, the additional gas can be added to the process gas at other locations in the vapor distribution system 30 and the process chamber 10 without departing from the scope of the invention. According to embodiments of the invention, the additional gas can be utilized to control the CO partial pressure in the process chamber 10. A partial pressure is the pressure that a component of a gaseous mixture would have if it alone occupied the same volume at the same temperature as the mixture. The CO partial pressure in the process chamber is calculated from the relative CO gas flow (e.g., CO gas flow divided by the combined inert gas and CO gas flow). According to one embodiment, the additional gas can be utilized to flow additional CO gas to the process gas in the processing zone 33 above the substrate 25 in the process chamber 10 after the process gas passes through the vapor distribution plate 34. According to embodiments of the invention, a flow rate of the additional CO gas can range from approximately 10 sccm to approximately 1000 sccm. Alternately, the flow rate of the additional CO gas can be between about 100 sccm and about 300 sccm.

Still referring to FIG. 1, the deposition system 1 can further include a control system 80 configured to operate and control the operation of the deposition system 1. The control system 80 is coupled to the process chamber 10, the substrate holder 20, the substrate temperature control system 22, the chamber temperature control system 12, the vapor distribution system 30, the vapor precursor delivery system 40, the metal precursor vaporization system 50, the vaporization temperature control system 54, and the gas supply system 60.

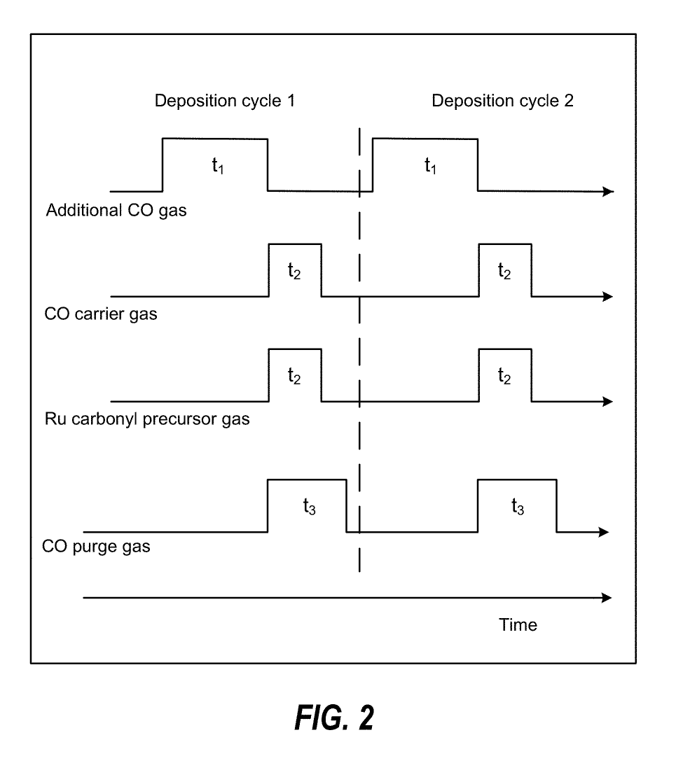

FIG. 2 schematically shows gas flows during cyclical Ru metal deposition according to an embodiment of the invention. The cyclical deposition process includes a plurality of deposition cycles that use a process gas containing CO carrier gas and a Ru carbonyl precursor gas, and an additional CO gas. The cyclical deposition process includes flowing the additional CO gas for a time period t₁, and flowing the CO carrier gas and the Ru carbonyl precursor gas for a time period t₂, where t₁ is greater than t₂, for example t₁>2t₂. The additional CO gas exposes the deposited Ru metal to CO for adsorbing CO species on the deposited Ru metal when the CO carrier gas and a Ru carbonyl precursor gas are not flowing. A CO purge gas is flowed for a time period t₃ to purge or clear out the Ru carbonyl precursor from the process chamber. The additional CO gas and the CO purge gas may be provided by more than one gas line in the process chamber. Only two deposition cycles are shown but any number of deposition cycles may be used until the Ru metal film has a desired thickness. Although not shown in FIG. 2, an inert gas such as Ar or N₂ may be flowed through the process chamber between deposition cycles. According to one embodiment, a flow rate of the additional CO gas can be greater than the flow of the CO purge gas. This results in greater CO gas exposure and thus adsorption of the CO species on the deposited Ru metal during time period t₁ than during time period t₃. In one example, a gas flow rate of the additional CO gas can be about 200 sccm, a gas flow rate of the CO carrier gas can be about 200 sccm, and a gas flow rate of the CO purge gas can be about 100 sccm.

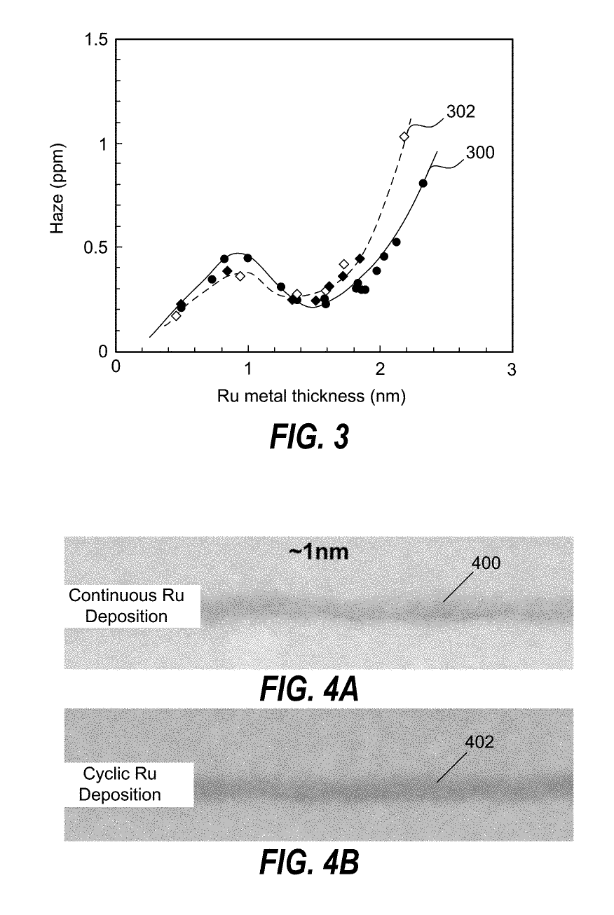

FIG. 3 shows measured haze of Ru metal films as a function of Ru metal thickness and deposition method according to an embodiment of the invention. The haze of the Ru metal films was measured using a light scattering technique. Trace 300 shows the haze results for Ru metal films deposited using continuous gas flow of CO carrier gas and a Ru carbonyl precursor gas, and trace 302 shows the haze results for Ru metal film deposited using cyclic deposition described above in FIG. 2. Time period t₂ was 2 seconds and 5 seconds, the substrate temperature was 195° C., and the process chamber pressure was 100 mTorr. The results show that the cyclic deposition resulted in lower haze for Ru metal film thicknesses up to about 1.4 nm. The lower haze is attributed to smoother and more continuous Ru metal films deposited by the cyclic deposition.

FIGS. 4A and 4B show cross-sectional TEM images of 1 nm thick Ru metal films according to an embodiment of the invention. FIG. 4A shows a Ru metal film deposited using a continuous gas flow of CO carrier gas and Ru₃(CO)₁₂ gas, and FIG. 4B shows a Ru metal film deposited by cyclic deposition. Visual comparison of the two TEM images shows that the Ru metal film 402 (dark horizontal region) in FIG. 4B deposited by cyclic deposition is smoother than the Ru metal film 400 in FIG. 4A deposited by continuous deposition.

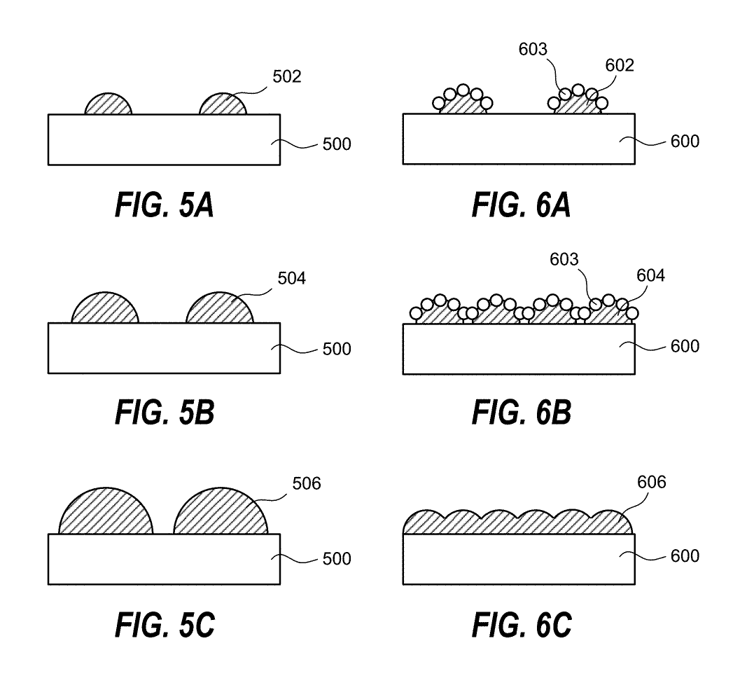

FIGS. 5A-5C schematically show through cross-sectional views continuous Ru metal deposition without the use of additional CO gas. As shown in FIG. 5A, initially, small Ru metal nuclei 502 are formed on the substrate 500 and further Ru metal deposition shown in FIGS. 5B and 5C preferentially forms larger Ru metal nuclei 504 and 506, respectively, with open areas on the substrate 500. In contrast, the cyclic deposition using additional CO gas shown in FIG. 6A-6C forms Ru metal nuclei 602 on the substrate that contain adsorbed CO species 603 that hinder further Ru metal deposition on the Ru metal nuclei 602, resulting in numerous small Ru metal nuclei 604 in FIG. 6B and a more uniform and continuous Ru metal film 606 in FIG. 6C.

The cyclic deposition described in embodiments of the invention uses the additional CO gas flow and optionally a CO purge gas for saturating Ru metal nuclei on the substrate with adsorbed CO species when the Ru carbonyl precursor gas is not flowing. The adsorbed CO species hinder further Ru metal deposition on the Ru metal nuclei. Without the adsorbed CO species on the Ru metal nuclei, further Ru metal deposition proceeds faster on Ru metal nuclei than on the substrate between the Ru metal nuclei. The inventors have realized that flowing the additional CO gas and optionally a CO purge gas when the Ru deposition is interrupted, improves the saturation of the adsorbed CO species on the Ru metal nuclei, and this results in more uniform and continuous Ru metal film. Cu metallization on uniform and continuous Ru metal films is preferred for improved electrical properties of the microelectronic devices.

Embodiments of the invention may be applied to substrates defining features to receive a deposition of material such as Ru metal. The features can, for example, include a trench or a via. The feature diameter can be less than 30 nm, less than 20 nm, less than 10 nm, or less than 5 nm. The feature diameter can be between 20 nm and 30 nm, between 10 nm and 20 nm, between 5 nm and 10 nm, or between 3 nm and 5 nm. A depth of the feature can, for example be greater 20nm, greater than 50 nm, greater than 100 nm, or greater than 200 nm. The features can, for example, have an aspect ratio (AR, depth:width) between 2:1 and 20:1, between 2:1 and 10:1, or between 2:1 and 5:1. In one example, the substrate (e.g., Si) includes a dielectric layer and the feature is formed in the dielectric layer.

Methods for depositing smooth and continuous Ru metal films for microelectronic devices have been described in several embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting.

Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method for material deposition, the method comprising:
providing a substrate defining features to receive a deposition of material;
initiating a flow of a ruthenium (Ru) carbonyl precursor to the substrate, the Ru carbonyl precursor decomposing within the defined features such that a Ru metal film is deposited on surfaces of the defined features and carbon monoxide (CO) gas is released;
stopping the flow of the Ru carbonyl precursor to the substrate;
flowing additional CO gas to the substrate after stopping the flow of the Ru carbonyl precursor to the substrate; and
repeatedly cycling between process steps of flowing the Ru carbonyl precursor to the substrate and flowing the additional CO gas to the substrate.

2. The method of claim 1, wherein a sufficient volume of the additional CO gas is flowed to the substrate to increase the density of Ru metal nuclei on the substrate as compared to the density of the Ru metal nuclei on the substrate without presence of the additional CO gas.

3. The method of claim 1, wherein the flow of the Ru carbonyl precursor further contains a CO carrier gas.

4. The method of claim 1, wherein the Ru carbonyl precursor contains Ru₃(CO)₁₂.

5. The method of claim 1, wherein the flow of the additional CO gas is initiated and stopped before the flow of the Ru carbonyl precursor is initiated.

6. The method of claim 1, further comprising initiating flow of CO purge gas to the substrate when the flow of the Ru₃(CO)₁₂ to the substrate is initiated.

7. The method of claim 1, wherein the repeatedly the cycling between process steps of flowing the Ru carbonyl precursor to the substrate and flowing the additional CO gas to the substrate forms a Ru metal film having a thickness of about 1.5 nm or less.

8. The method of claim 1, wherein the repeatedly the cycling between process steps of flowing the Ru carbonyl precursor to the substrate and flowing the additional CO gas to the substrate forms a Ru metal film having a thickness of about 1 nm.

9. A method for material deposition, the method comprising:
providing a substrate defining features to receive a deposition of material;
initiating a flow of Ru₃(CO)₁₂ and carbon monoxide (CO) carrier gas to the substrate, the Ru₃(CO)₁₂ decomposing within the defined features such that a Ru metal film is deposited on surfaces of the defined features and CO gas is released;
stopping the flow of the Ru₃(CO)₁₂ and the CO carrier gas to the substrate;
flowing additional CO gas to the substrate after stopping the flow of the Ru₃(CO)₁₂ and the CO carrier gas to the substrate; and
repeatedly cycling between process steps of flowing the Ru₃(CO)₁₂ and the CO carrier gas to the substrate and flowing the additional CO gas to the substrate, wherein a sufficient volume of the additional CO gas is flowed to the substrate to increase the density of Ru metal nuclei on the substrate as compared to the density of the Ru metal nuclei on the substrate without presence of the additional CO gas.

10. The method of claim 9, wherein the flow of the additional CO gas is initiated and stopped before the flow of the Ru₃(CO)₁₂ is initiated.

11. The method of claim 9, further comprising
initiating flow of CO purge gas to the substrate when the flow of the Ru₃(CO)₁₂ to the substrate is initiated.

12. The method of claim 9, wherein the repeatedly the cycling between process steps of flowing the Ru₃(CO)₁₂ to the substrate and flowing the additional CO gas to the substrate forms a Ru metal film having a thickness of about 1.5 nm or less.

13. A method for material deposition, the method comprising:
providing a substrate defining features to receive a deposition of material;
initiating a flow of a ruthenium (Ru) carbonyl precursor to the substrate, the Ru carbonyl precursor decomposing within the defined features such that a Ru metal film is deposited on surfaces of the defined features and carbon monoxide (CO) gas is released;
stopping the flow of the Ru carbonyl precursor to the substrate;
initiating a flow of additional CO gas to the substrate after stopping flow of the Ru carbonyl precursor to the substrate; and
stopping the flow of the additional CO gas to the substrate, and repeatedly cycling between process steps of flowing the Ru carbonyl precursor to the substrate and flowing the additional CO gas to the substrate.

14. The method of claim 13, wherein a sufficient volume of the additional CO gas is flowed to the substrate to increase the density of Ru metal nuclei on the substrate as compared to the density of the Ru metal nuclei on the substrate without presence of the additional CO gas.

15. The method of claim 13, wherein the flow of the Ru carbonyl precursor further contains a CO carrier gas.

16. The method of claim 13, wherein the Ru carbonyl precursor contains Ru₃(CO)₁₂.

17. The method of claim 13, wherein the flow of the additional CO gas is initiated and stopped before the flow of the Ru carbonyl precursor is initiated.

18. The method of claim 13, further comprising
initiating flow of CO purge gas to the substrate when the flow of the Ru carbonyl precursor to the substrate is initiated.

19. The method of claim 13, wherein the repeatedly the cycling between process steps of flowing the Ru carbonyl precursor to the substrate and flowing the additional CO gas to the substrate forms a Ru metal film having a thickness of about 1.5 nm or less.

20. The method of claim 13, wherein the repeatedly the cycling between process steps of flowing the Ru carbonyl precursor to the substrate and flowing the additional CO gas to the substrate forms a Ru metal film having a thickness of about 1 nm.
